(19) United States
(12) Patent Application Publication
(10) Pub. No.: US 2009/0161333 A1
(43) Pub. Date: Jun. 25, 2009

(54) Auto-cling leads of electric device

(76) Inventor: Kevin Yang, Palos Verdes Est., CA (US)

Correspondence Address: LAW OFFICES OF CLEMENT CHENG, 17220 NEWHOPE STREET #127, FOUNTAIN VALLEY, CA, 92708, US

(21) Appl. No.: 12/002,910

(22) Filed: Dec. 19, 2007

(51) Int. Cl. H05K 7/18

(52) U.S. Cl. 361/813

(57) ABSTRACT

Automatic clinging leads of an electric device are provided for an unassisted mounting on thru-holes of a printed circuit board. Each of the leads of the device has three continuous right-angled sections including a longitudinal proximal end section extending from the terminal region of the electric element, a latitudinal distal end section extending at right angle with respect to the proximal end section, and a bent midsection for connecting the proximal and distal end sections at the diametrically opposite right angle to the angle between the proximal and distal end sections to provide a generally laterally extending lead with three alternating bends between the three sections. The device leads can be inserted into the thru-holes of the circuit board through a 90-degree swivel motion that causes a secure flush cling of the leads and in turn a low profile mounting of the device onto the circuit board around thru-holes.

### BACKGROUND OF THE INVENTION

A. Field of the Invention

The present invention relates to electric components. More particularly, the present invention relates to shaped connection leads of electric devices for improving the initial positioning of the devices on a circuit board at assembly.

B. Description of the Prior Art

Conventionally, an electric component or device such as a transistor 1 shown in FIGS. 1 and 2 has multiple electrical connections of terminals or leads 2, usually a set of wires, coming off the transistor 1 in order to make connection to another on a substrate commonly called a printed circuit board (PCB) 3. The leads 2 function to transfer power, transmit signal in and out of the transistor 1 and are used in probing a circuit implemented on PCB 3. Upon completion of an insertion at thru-holes 4 of PCB 3 followed by a soldering process, the leads 2 enter electrical i s connections permanently via bodies of solder 5 to their designated circuit terminals on the PCB 3. The leads 2 are made to extend straight and girthed to be relatively thin so that little or no force is applied for insertion into the hole 4. Therefore, the device 1 lacks a positive holding means for temporarily setting the correct position of the device 1 with respect to PCB 3 and needs an external assistance for such positioning, which is essential in achieving a prolonged reliable performance of the resulting circuitry in a multitude of harsh environments. Furthermore, the thin extension of leads 2 causes thickening of the bodies of solder 5 and thus the overall circuit unit failing to take advantage of an ample area at the underside of PCB 3, which is normally void of components.

FIG. 3 shows pointing pins 6 and its surrounding solder formations 5 in a tightly restricted area of PCB 3 in comparison to the device 1.

In order to solve the above or other problems, numerous suggestions have been made. U.S. Pat. No. 4,541,034 to Fanning discloses a special design of thru-hole insertable terminal that has multiple bends as well as a free-ended tab formed internally of the terminal by a blanking or die cut. The Fanning terminals each requires a tab bending after insertion of the terminal for the purpose of a temporary securement as a prerequisite to a permanent soldering process which calls for a dedication of energy and precious machine time. Besides, the formation of a deflection tab through a blanking process limits the choice of material to make such terminals to be flat or in a blade shape although the majority of component leads are cuts of thin wires or rods with round cross sections. It is impractical if not impossible to form a bending tab amid a run of a thin wire. Adding to that difficulty of actual manufacturing is the complex machine dynamics to process the temporary and permanent securements in an automated assembly line. I.e., Fanning terminals need three distinctive movements of vertical insertion of the component and two opposite deflections of the tabs inside the thru-holes.

U.S. Pat. No. 7,045,720 to Sagayanathan, et al. suggests a component lead system having two opposing leads shaped into a clip to hold a substrate or circuit board area between thru-holes. Each lead is made of different leg sections that are normally under bias rendering downward or upward insertion of the component more difficult which means more energy input is needed just to overcome the excess of bias.

Other similar patents include U.S. Pat. No. 3,747,045 to Stross; U.S. Pat. No. 5,726,862 to Huynh et al.; U.S. Pat. No. 5,586,008 to Kozel et al. However, none of these component leads take a simple uniform shape that can be applied to different types of lead material to effectuate a single action flipped insertion of components, thereby completing a secure cling of the same to the designated positions on the circuit board.

In view of these shortcomings of the existing component terminals and leads, an objective of the present invention is to provide auto-cling leads of electric components that allow an unassisted fastening of components onto a circuit board.

Another objective of the present invention is to provide a standardized shape of components leads regardless of their material type that will result in the same reliable cling of the components until they are permanently soldered to the circuit board, and also be stronger after being soldered to the circuit board.

Yet another objective of the present invention is to provide leads can be inserted into the thru-holes of the circuit board through a 90-degree swivel motion that causes a secure flush cling of the leads and in turn a low profile mounting of the electric component onto the circuit board around the thru-holes.

### SUMMARY OF THE INVENTION

In accordance with the present invention, automatic clinging leads of an electric device are provided for an unassisted mounting on thru-holes of a printed circuit board. The electric device may be either an active or passive electronic component that comprises an electric element extending in a longitudinal direction and having a predetermined conduction function. There are multiple terminal regions formed on the electric element for making electrical connections of the same with another element on the circuit board. The electric device also comprises conductive leads each having three continuous right-angled sections including a longitudinal proximal end section extending from the terminal region of the electric element, a predetermined length of latitudinal distal end section extending at right angle with respect to the proximal end section, and a bent midsection for connecting the proximal and distal end sections at the diametrically opposite right angle to the angle between the proximal and distal end sections meeting at a cross of their imaginary projection lines to provide a generally laterally extending lead with three alternating bends between the three sections. With such electric device, an insertion of the leads through a 90-degree swivel motion into the thru-holes of the circuit board causes a secure flush cling of the leads and in turn a low profile mounting of the electric device onto the circuit board around the thru-holes.

The auto-cling leads are in a blade shape and have a flat cross section. Alternatively, the leads are in a rod shape and have a round cross section.

Embodiments of the invention will now be described by way of example with reference to the accompanying drawings.

### BRIEF DESCRIPTION OF THE DRAWINGS

FIG. 1 is a perspective view of a typical electric device having plain terminal leads prior to the present invention.

FIG. 2 is a partial cross sectional view of a prior art assembly of the electric device of FIG. 1 on a circuit board.

FIG. 3 is a bottom view of the circuit board of FIG. 2.

FIG. 4 is a perspective view of an electric component with three auto-cling leads of a flat blade type according to an embodiment of the present invention.

FIG. 5 is a partial cross sectional view of the auto-cling component of FIG. 4, showing the secure hold between the component and circuit board before and after the soldering process.

FIG. 6 is a top view of the auto-cling component mounted on the circuit board.

FIG. 7 is a bottom view of the circuit board showing clipping pins completely soldered onto printed circuit portions underside of the board.

FIG. 8A is a partially sectional side elevational view of the auto-cling component of FIG. 4, showing the component initially aligned to a thru-hole of the board.

FIG. 8B is a side elevational view similar to FIG. 8A, showing a second position of the component in the thru-hole wherein the component is in substantially parallel position to the board.

FIG. 8C is a side elevational view showing the component in the thru-hole at a third transitional position.

FIG. 8D is a side elevational view showing the component in the thru-hole at a fourth transitional position.

FIG. 8E is side elevational view showing the component snugly grasping the board at opposite surfaces as it threads through the hole in a thin mounting position with no bending of the leads involved according to the present invention.

FIG. 9 is a perspective view of an electric component with two auto-cling leads in a rod type according to an alternative embodiment of the present invention.

FIG. 10 is a partial cross sectional view of the auto-cling component of FIG. 10, showing the secure hold between the component and circuit board before and after the soldering process.

FIG. 11 is a top view of the auto-cling component mounted on the circuit board.

FIG. 12 is a bottom view of the circuit board showing clipping pins completely soldered onto printed circuit portions underside of the board.

FIG. 13A is a partial cross sectional view of the auto-cling component of FIG. 10, showing the component initially aligned to a thru-hole of the board.

FIG. 13B is a side elevational view similar to FIG. 8A, showing a first position of the component in the thru-hole, showing the component is in substantially parallel position to the board.

FIG. 13C is a side elevational view showing the component in the thru-hole at a third transitional position.

FIG. 13D is side elevational view showing the component in the thru-hole at a fourth transitional position.

FIG. 13E is a side elevational view showing the component snugly grasping the board at opposite surfaces as it threads through the hole in a thin mounting position with no subsequent bending of the leads involved according to the present invention.

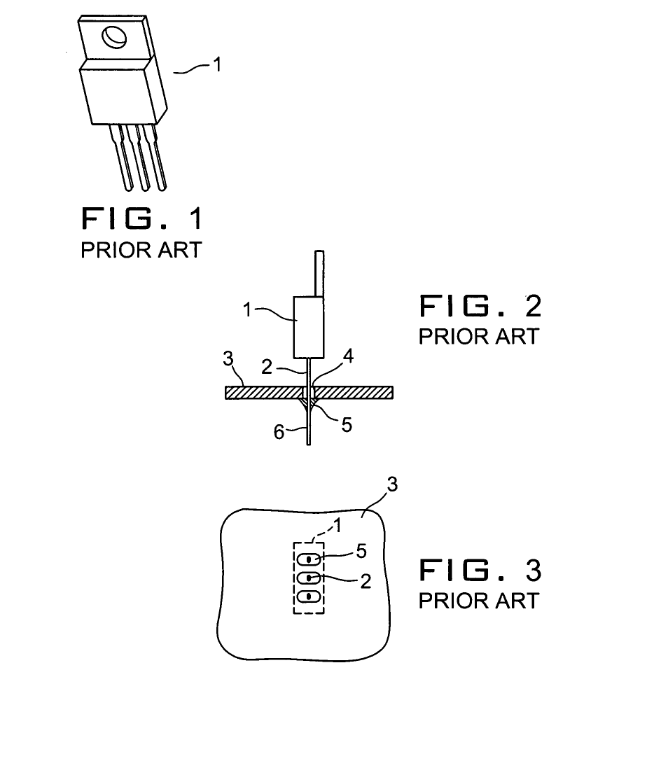

Similar reference numbers denote corresponding features throughout the attached drawings.
1 transistor
2 leads
3 printed circuit board (PCB)
4 hole
5 solder formations
6 pointing pins
10 electronic circuit
50 solder
60 transistor device
70 printed circuit board
72 hole
80 leads
81 longitudinal proximal end section
82 first 90-degree bend
83 shank
84 second 90-degree bend
85 third 90-degree bend
86 pin
87 tip
88 third vertical straight section
90 hole
100 electronic circuit
160 device
180 leads
181 first straight section
182 first 90-degree bend
183 shank
184 second 90-degree bend
185 third 90-degree bend
186 pin
187 tip
188 third straight section

### DETAILED DESCRIPTION OF THE PREFERRED EMBODIMENT

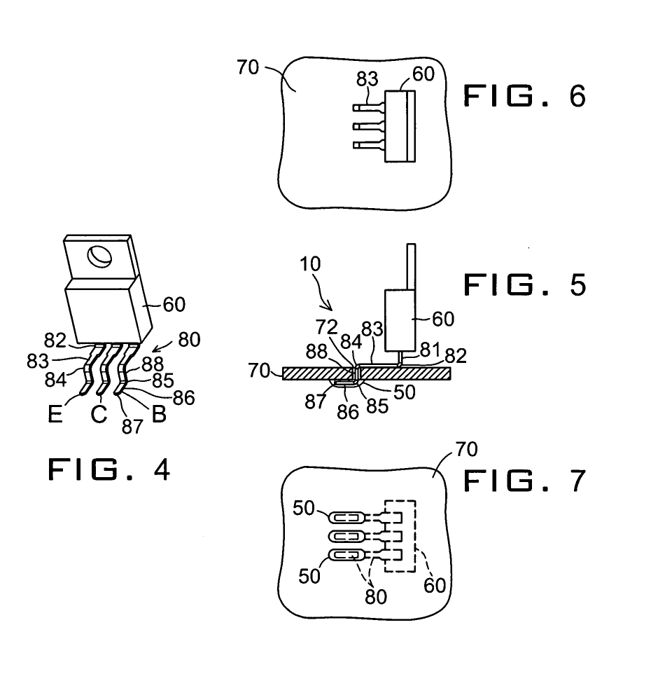

With reference to FIGS. 4 and 5 showing an exemplary electric device 60 of the present invention, the device 60 is a transistor with three leads 80 including an emitter E, base B and collector C, which are conductor blades identically formed into a lobster leg according to the present invention and thus will be referenced interchangeably to indicate different features of one of the leads. In FIG. 5, the device 60 is secured on PCB 70 to form a part of an electronic circuit 10. The lead configuration according to the present invention may be applied to manufactured leads of finished electric components or to shaping flat or round leads before a bonding process thereof onto conduction terminals inside an encapsulating package from which the leads 80 will extend.

Lead 80 has a first straight section 81 extending vertically from a bottom side of device 60 that stands substantially upright from a PCB 70. PCB 70 has a plurality of thru-holes including a hole 72. The lower limit in sizing a PCB thru-hole is supposed to be set to slightly exceed the largest girth or diameter of the leads of components mounted to accommodate them with little resistance. Different PCBs have had individually sized thru-holes for specified devices with leads although they are more expensive to make.

The drawings depict that transistor device 60 may have a stop shaped on each of the leads to show the present invention applied to existing manufactured components although such stops or individual hole sizing may not be necessary thanks to the present invention. Further, according to the present invention, the upper limit of hole 72 also becomes free of a tight tolerance without a concern of displacement of device 60 before and after a subsequent soldering process since the lead of device 60 is adapted to hold device 60 onto PCB 70 without having to engage hole 72.

Instead, a second straight section of a flat shank 83 extends from first section 81 via a first 90-degree bend 82 to make a flat engagement with PCB 70 at its dielectric upper surface. A vertical third straight section 88 of the lead penetrating the hole 72 interconnects the shank 83 via a second 90-degree bend 84 and the fourth straight section of a horizontal pin 87 via a third 90-degree bend 85. The spaced second and third bends 84, 85 along with the connecting straight section 88 work in unity as a pivoting means when inserting device 60 into hole 72 during assembly. Pin 86 is terminated by a tip 87, which is under gravity biased toward a circuit trace (not shown) until a mass of solder 50 is formed to cover the whole pin 86 connecting the same to PCB 70 electrically for good.

Therefore, each of leads 80 of the electric device constitutes three continuous right-angled sections including longitudinal proximal end section 81 extending from the internal terminal region of the electric device, latitudinal distal end section 86 extending at right angle with respect to the proximal end section 81, and bent midsection 83/88 for connecting the proximal and distal end sections 81, 86 at the diametrically opposite right angle to the angle between the proximal and distal end sections 81, 86 meeting at a cross of their imaginary projection lines to have the lead 80 extending generally laterally with three alternating bends 82, 84 and 85 between the three right-angled sections.

FIG. 6 clearly shows in plan view the flat shanks 83 after assembly of device 60 while FIG. 7 shows the same in bottom view. Although the length of shanks 83 is depicted liberally for illustration, it can be shorter to take up less area on the PCB 70 as long as the pivoting unit 84, 85 is distanced from the center of gravity of device 60 to effectuate the flip down mounting of the same. Solder 50 conforms to the length of pin 86 and lies flat on the PCB 70 reducing the overall thickness of the electronic circuit 10.

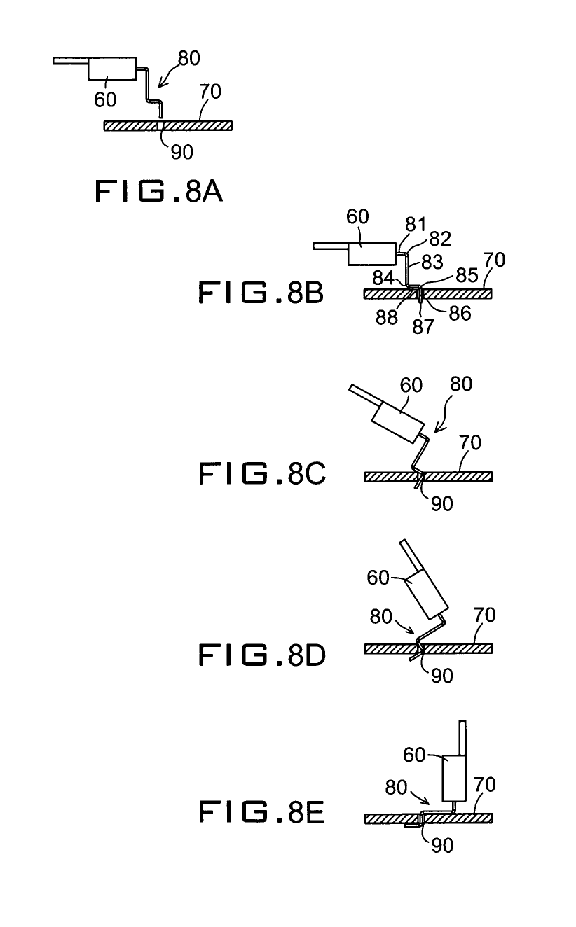

FIG. 8A depicts an alignment of the leads 80 of device 60 to the hole 90 of PCB 70 wherein device 60 is oriented in parallel with PCB 70 facing each other at one upper side so that pin 86 extends in the same direction as the hole 90. Here, PCB 70 is positioned upright with the components side on top and the circuit traces for soldering facing down.

In step two of FIG. 8B, the leads 80 are in the initial position inside the PCB 70 that is defined by a temporary hold of section 88 onto the upper surface of PCB 70 at around the hole 90. Then, as shown in two split views in step three of FIG. 8C and step four of FIG. 8D, device 60 goes through a smooth flip action taking advantage of the structural resistance of the flexible bend 85 of pin 86 and the penetrating section 88. As each of the leads 80 slides against the inner wall of the hole 90 about its pivoting unit 84/85, the length and weight of device 60 itself are utilized as a leverage in overcoming the resistance, which is only transitional. Then, in step five of FIG. 8E the device 60 ends its 90-degree swivel toward the other upper side of PCB 70 to complete the insertion. FIG. 8E shows the mounted position of device 60 on PCB 70 which is ready to undergo a soldering process.

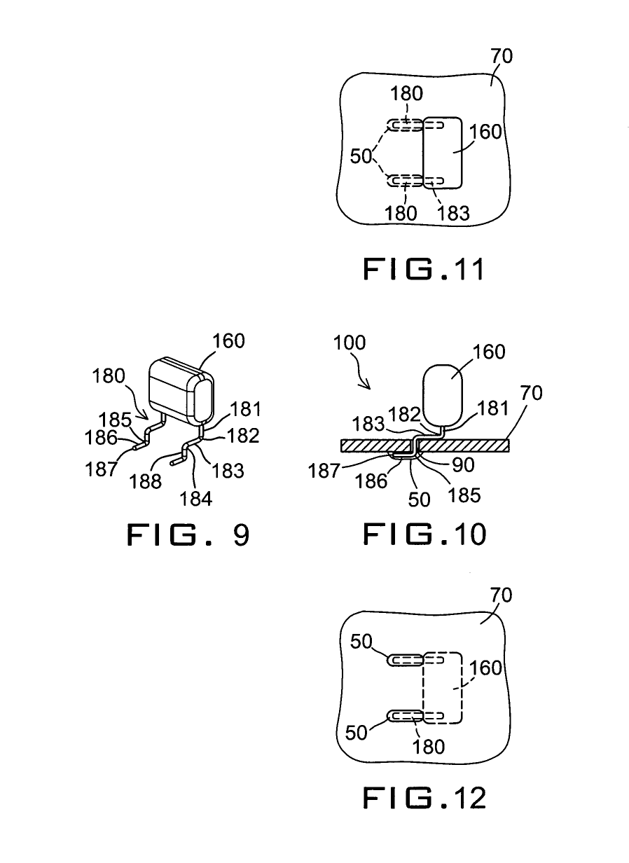

FIGS. 9 to 12 show a second electronic device 160 of the present invention that is a capacitor with two leads 180, which are conductor rods similarly shaped to the lobster legs of the device 60 of the first embodiment. Both capacitor leads 180 have a common shape and thus will be referenced interchangeably to indicate different features of one of the leads. In FIG. 10, the device 160 is secured on PCB 70 to form a part of an electronic circuit 100.

Each of the leads 180 has a first straight section 181 extending vertically from a bottom side of device 160 that stands substantially upright from PCB 70 penetrating a thru-hole 172 of PCB 70. The lower limit in sizing a PCB thru-hole is supposed to be set to slightly exceed the largest diameter of the round leads of components mounted to accommodate them with little resistance. The upper limit of hole 172 needs not to be within a tight tolerance without a concern of displacement of device 160 before and after a subsequent soldering process since the lead 180 holds device 160 onto PCB 70 without having to engage hole 172.

Second straight section of a parallel shank 183 extends from first section 181 via a first 90-degree bend 182 to make a flat engagement with PCB 70 at its dielectric upper surface. A vertical third straight section 188 of the lead running through the hole 172 interconnects the shank 183 via a second 90-degree bend 184 and the fourth straight section of a horizontal pin 187 via a third 90-degree bend 185. The spaced second and third bends 184, 185 along with the connecting straight section 188 work in unity as a pivoting body when inserting device 160 into hole 172 during assembly.

Pin 186 is terminated by a tip 187, which is under gravity biased toward a circuit trace (not shown) until a mass of solder 50 is formed to cover the whole pin 186.

FIG. 11 clearly shows in plan view the parallel shanks 183 after assembly of device 160 while FIG. 12 shows the same in bottom view. The length of shanks 183 may be shorter than illustrated to take up less area on the upper surface of PCB 70 as long as the pivoting body 184/185 is distanced from the center of gravity of device 160 to contribute to the flip down mounting of the same. Solder 50 may extend along the length of pin 186 and lies flat on the PCB 70 reducing the overall thickness of the electronic circuit 100.

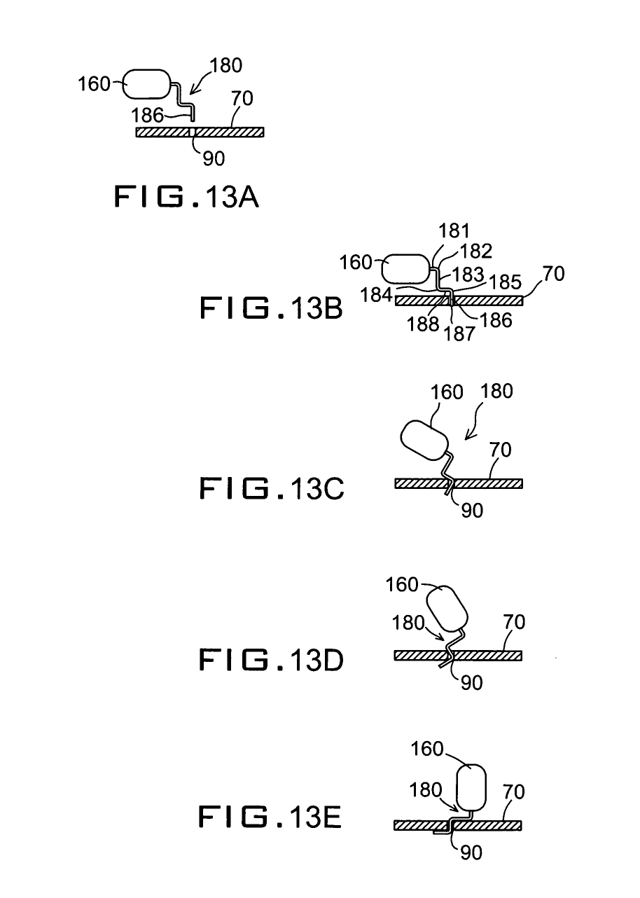

FIG. 13A depicts step one to align the leads 180 of device 160 to the hole 90 of PCB 70 wherein device 160 is oriented in parallel with PCB 70 facing each other at one upper side of PCB 70 so that pin 186 extends in the same direction as the hole 90. Here, PCB 70 is positioned upright with the components side on top and the circuit traces for soldering facing down. In addition, PCB 70 with a single side circuit trace or one without plated thru-holes is suffice to work perfectly with the inventive auto-cling device 160 thus assembling the circuit 100 becomes more economical as well as uniform.

In step two of FIG. 13B, the lead 180 is in its initial position inside PCB 70 that is defined by a temporary hold of section 188 onto the upper surface of PCB 70 at around the hole 90. Then, as shown sequentially in step three of FIG. 13C to step five of FIG. 13E the device 160 held is pivoted over 90 degrees about its pivoting body 184/185 toward the other upper side of PCB 70. FIG. 3E shows the final position of device 160 on PCB 70 which is ready to be subjected to a soldering process.

The electric device can be made as a transformer, transistor or capacitor. A wire bending machine can easily wire bend any of the leads of these common electrical devices into the stepped profile as shown in the drawings. The stepped profile provides an easier connection and more durable connection than the connection of the prior art.

Therefore, while the presently preferred form of the automatic clinging leads of electric devices have been shown and described, and several modifications thereof discussed, persons skilled in this art will readily appreciate that various additional changes and modifications may be made without departing from the spirit of the invention, as defined and differentiated by the following claims.

1. An electric device having automatic clinging leads for an mounting on thru-holes of a printed circuit board comprising:
an electric element extending in a longitudinal direction and having a predetermined conduction function;
multiple terminal regions formed on the electric element for making electrical connections of the same with another element on the circuit board; and
conductive leads each having three continuous right-angled sections including a longitudinal proximal end section extending from the terminal region of the electric element, a predetermined length of latitudinal distal end section extending at right angle with respect to the proximal end section, and a bent midsection for connecting the proximal and distal end sections at the diametrically opposite right angle to the angle between the proximal and distal end sections meeting at a cross of their imaginary projection lines to provide a generally laterally extending lead with three alternating bends between the three sections, whereby an insertion of the leads through a 90-degree swivel motion into the thru-holes of the circuit board causes a secure cling of the leads and in turn the electric device onto the circuit board around the thru-holes.

2. The automatic clinging leads of an electric device of claim 1, wherein leads are in a blade shape and have a flat cross section.

3. The automatic clinging leads of an electric device of claim 1, wherein the leads are in a rod shape and have a round cross section.

4. An electric device having clinging leads for mounting on thru-holes of a printed circuit board comprising:
an electric element extending in a longitudinal direction and having a predetermined conduction function;
multiple terminal regions formed on the electric element for making electrical connections of the same with another element on the circuit board; and
conductive leads each having three continuous right-angled sections comprising:
a first straight section of a flat shank extending from first section via a first 90-degree bend to make a flat engagement with the circuit board at its dielectric upper surface;
second straight section;
a vertical third straight section of each conductive lead penetrating a hole interconnecting the shank via a second 90-degree bend;
and a fourth straight section of a horizontal pin via a third 90-degree bend,
wherein the spaced second and third bends along with the connecting straight section work in unity as a pivoting means when inserting the electric element into the hole during assembly.

5. The automatic clinging leads of an electric device of claim 4, wherein leads are in a blade shape and have a flat cross section.

6. The automatic clinging leads of an electric device of claim 4, wherein the leads are in a rod shape and have a round cross section.

7. The automatic clinging leads of an electric device of claim 4, wherein the electric device further comprises solder attaching the device to the circuit board, wherein the solder comprises a bead shape and attaches between the circuit board and the fourth straight section, wherein the solder makes electrical connection between the circuit board and the fourth straight section.

8. The automatic clinging leads of an electric device of claim 7, wherein leads are in a blade shape and have a flat cross section.

9. The automatic clinging leads of an electric device of claim 7, wherein the leads are in a rod shape and have a round cross section.

10. The automatic clinging leads of an electric device of claim 7, wherein the electric device is a transistor, capacitor or transformer.

11. An electric device having clinging leads for mounting on thru-holes of a printed circuit board comprising:
an electric element extending in a longitudinal direction and having a predetermined conduction function;
multiple terminal regions formed on the electric element for making electrical connections of the same with another element on the circuit board; and conductive leads each having three continuous right-angled sections that form a stepped profile conforming to a through hole of the circuit board.

12. The automatic clinging leads of an electric device of claim 11, wherein leads are in a blade shape and have a flat cross section.

13. The automatic clinging leads of an electric device of claim 11, wherein the leads are in a rod shape and have a round cross section.

14. The automatic clinging leads of an electric device of claim 11, wherein the electric device is a transistor, capacitor or transformer.
